(19) United States
(12) Patent Application Publication
(10) Pub. No.: US 2009/0251198 A1
(43) Pub. Date: Oct. 8, 2009

(54) Circuit Arrangement and Method for Driving an Electronic Component With an Output Signal From a Microprocessor

(75) Inventor: Bernd Rudolph, Forstern (DE)

Correspondence Address: OSRAM SYLVANIA INC, 100 ENDICOTT STREET, DANVERS, MA, 01923, US

(73) Assignee: OSRAM GESELLSCHAFT MIT BESCHRANKTER HAFTUNG, Munchen (DE)

(21) Appl. No.: 12/085,283

(22) PCT Filed: Nov. 21, 2006
(86) PCT No.: PCT/EP2006/068722

§ 371 Date: May 21, 2008

(30) Foreign Application Priority Data
Nov. 23, 2005 (DE) 10 2005 055 832.1

(51) Int. Cl. H03K 17/60; H03K 17/56

(52) U.S. Cl. 327/482; 327/419

(57) ABSTRACT

A circuit arrangement for driving an electronic component with the output signal (V6) from a microprocessor (MP), includes: the electronic component with a control input; a microprocessor (MP), which provides an output signal (V6) at an output (A1); wherein it furthermore includes: a first bipolar transistor (Q5) in common-base connection, whose emitter is coupled to the output (A1) of the microprocessor (MP); a second bipolar transistor (Q7) in common-emitter connection, whose base is coupled to the collector of the first bipolar transistor (Q5), wherein the collector of the second bipolar transistor (Q7) is coupled to the control input of the electronic component. Moreover, it relates to a corresponding method for driving an electronic component with the output signal (V6) from a microprocessor (MP).

### TECHNICAL FIELD

The present invention relates to a circuit arrangement for driving an electronic component with an output signal from a microprocessor, comprising the electronic component with a control input, and the microprocessor, which provides an output signal at an output. Moreover, it encompasses a corresponding method for driving an electronic component with the output signal from a microprocessor.

### PRIOR ART

The present invention should be seen against the background that microprocessor controllers are increasingly making inroads into power electronics. A typical application here is the use for driving electronic insulated gate switches which statically are essentially voltage-controlled, for example MOSFET, IGBT, ESBT, for example for PFC (power factor correction) stages.

Directly driving such an electronic component with a signal provided by the microprocessor at an output, said signal usually having a voltage swing of the order of magnitude of 5 V, the trend being toward even lower voltages, fails since such electronic components require voltages of 10 V or more at their control input for reliable driving. Moreover, the microprocessor cannot operate powerful switches having appreciable input capacitances—the corresponding MOSFET parameter is called total gate charge—with high switching speeds since the necessary control currents cannot be provided.

In order to solve this problem, special integrated driver circuits are normally used which bring the level of the output signal of the microprocessor to a level suitable for driving the electronic component and can generate correspondingly high output currents for high switching speeds. However, the use of such driver circuits is disadvantageous on account of their complexity and the associated high costs.

### SUMMARY OF THE INVENTION

The object of the present invention consists, therefore, in providing a possibility by means of which an electronic component can be driven with the output signal from a microprocessor in a cost-effective manner.

This object is achieved firstly by means of a circuit arrangement having the features of patent claim 1, and secondly by means of a method having the features of patent claim 11.

The present invention is based on the insight that the object referred to above can be achieved if a combination of two bipolar transistors is connected as part of a driver stage between the output of the microprocessor and the control input of the electronic component, the bipolar transistor connected to the microprocessor being connected in common-base connection. This bipolar transistor drives the further bipolar transistor, which operates in common-emitter connection. As a result, on the one hand, a high switching speed is ensured even with inexpensive standard components, that is to say that there is no need to use any special RF transistors; on the other hand, the advantage of the circuit arrangement according to the invention is that in the event of failure of the supply voltage of the driver stage comprising these two bipolar transistors, no current flows into the relevant output of the microprocessor and influences the logic state thereof.

By driving the first bipolar transistor on the emitter side thereof, it is possible to use a higher current than if said bipolar transistor were driven via its base side. In this case, it is preferred if the base of the first bipolar transistor is coupled to the reference potential to which the microprocessor is coupled via one of its inputs, in particular for voltage supply.

In order to ensure high switching speeds even with inexpensive standard components, a first antisaturation diode can be coupled between the collector of the first bipolar transistor and the base of the second bipolar transistor and a second antisaturation diode can be coupled between the collector of the first bipolar transistor and the collector of the second bipolar transistor.

In order to enable the electronic component to be switched off rapidly, the circuit arrangement according to the invention preferably comprises a further transistor, preferably a logic level MOSFET, in particular an n-channel MOSFET, the control electrode of which is coupled to the output of the microprocessor, the reference electrode of which is coupled to a second reference potential, in particular to ground, and the working electrode of which is coupled to the control input of the electronic component. It is thus possible, moreover, to obtain the advantage of a very low quiescent current consumption of a circuit arrangement according to the invention.

Preferably, the control input of the electronic component is coupled to the second reference potential via a pull-down resistor in order that the electronic component is reliably turned off in the quiescent state even without an active control circuit.

The voltage swing of the output signal at the output of the microprocessor is preferably at most 6 V. Preferably, the first bipolar transistor is of the npn type, and the second bipolar transistor is of the pnp type. As already mentioned, the electronic component is an essentially voltage-controlled electronic component, in particular a MOSFET, an IGBT or an ESBT.

Further preferred embodiments emerge from the subclaims.

The preferred embodiments mentioned in connection with the circuit arrangement according to the invention and their advantages are correspondingly applicable to the method according to the invention.

### BRIEF DESCRIPTION OF THE DRAWING(S)

An exemplary embodiment of a circuit arrangement according to the invention will now be described in more detail below with reference to the accompanying drawings, in which:

FIG. 1 shows, in a schematic illustration, a circuit diagram of an exemplary embodiment of a circuit arrangement according to the invention;

FIG. 2 shows the temporal profile of different variables of the circuit arrangement from FIG. 1 in the case of switching on and switching off a MOSFET;

FIG. 3 shows the temporal profile of different variables of the circuit arrangement from FIG. 1 in an enlarged illustration in the case of switching on a MOSFET; and

FIG. 4 shows the temporal profile of different variables of the circuit arrangement from FIG. 1 in an enlarged illustration in the case of switching off a MOSFET.

### PREFERRED EMBODIMENT OF THE INVENTION

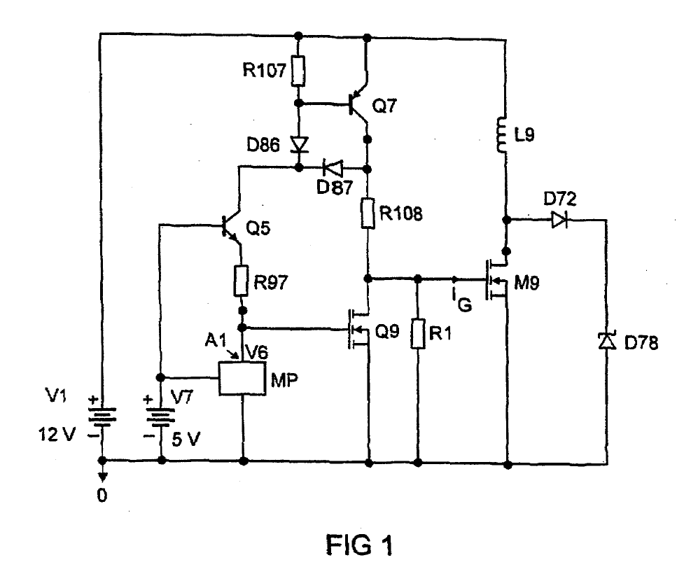

FIG. 1 shows, in a schematic illustration, a circuit diagram of a preferred exemplary embodiment of a circuit arrangement according to the invention. As is evident to the person skilled in the art with regard to the explanations below, some of the electronic components are governed by simulation. The circuit arrangement comprises a microprocessor MP, at the output A1 of which an output signal V6 is provided. Said output signal is applied via a resistor R97 to the emitter of a bipolar transistor Q5 in common-base connection. The base thereof is at the reference potential V7, which, in the exemplary embodiment, is 5 V and simultaneously serves for supplying the microprocessor MP. The collector of the bipolar transistor Q5 is connected to the base of a second bipolar transistor Q7, which is operated in common-emitter connection. The collector of the second bipolar transistor is connected via a resistor R108 to the control input, i.e. the gate, of a power switch, realized by the MOSFET transistor M9. A first antisaturation diode D86 is coupled between the collector of the first bipolar transistor Q5 and the base of the second bipolar transistor Q7, and a second antisaturation diode D87 is coupled between the collector of the first bipolar transistor Q5 and the collector of the second bipolar transistor Q7. The gate of the field effect transistor M9 is coupled to the drain terminal of a field effect transistor Q9, the source of which is connected to ground terminal, while the gate thereof is connected to the output A1 of the microprocessor MP. A pull-down resistor R1 is coupled between the gate of the field effect transistor M9 and the ground terminal. For the simulation of an inductive load, an inductance L9 is connected to the drain terminal of the field effect transistor, the drain terminal additionally being connected to the ground potential via the series circuit formed by a diode D72 and a zener diode D78. The driver stage, comprising the bipolar transistors Q5 and Q7, and also the field effect transistor Q9 and the field effect transistor M9 are supplied from a voltage source V1, which provides a voltage of 12 V in the present case.

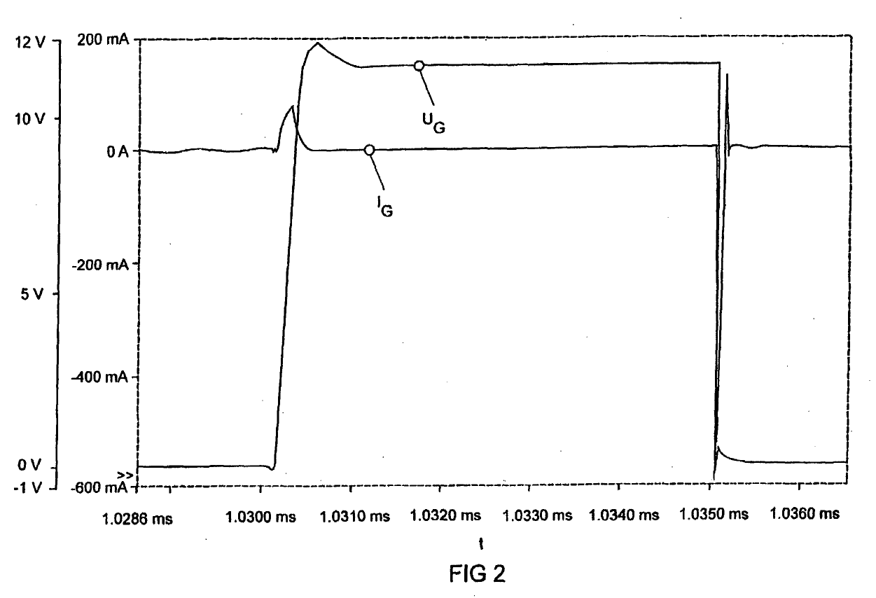

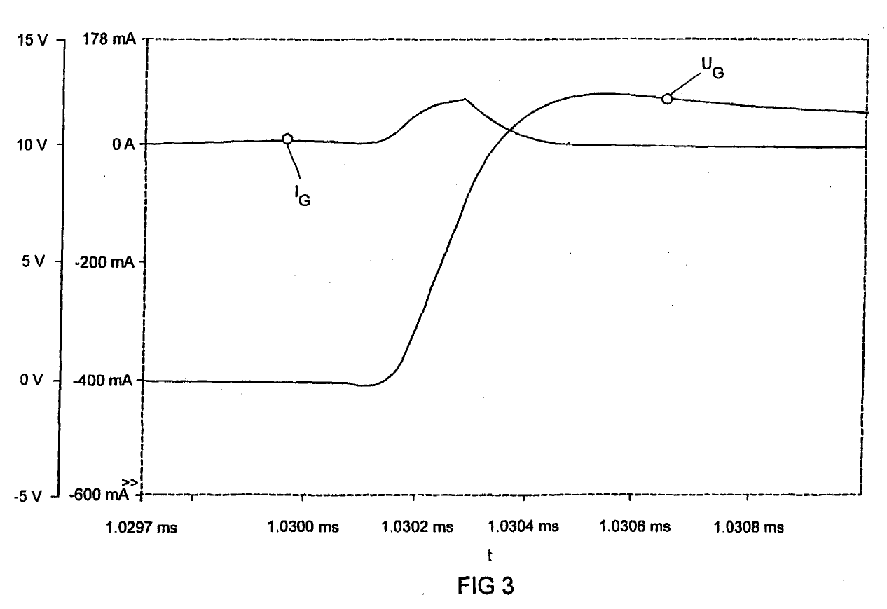

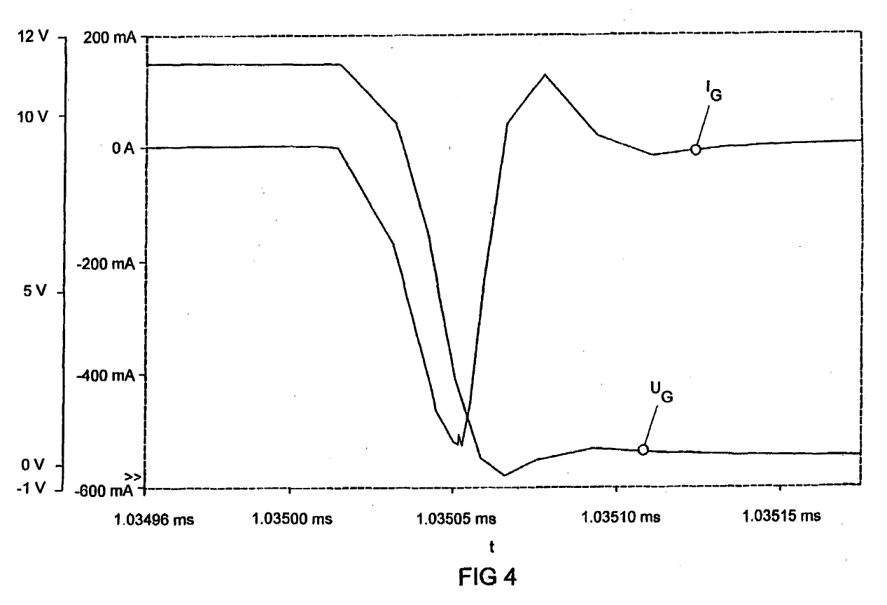

FIG. 2 shows the temporal profile of the gate current I_{G} and of the gate voltage U_{G} of the field effect transistor M9 in the case of switching on (left-hand half of the figure) and in the case of switching off (right-hand half of the figure). The switching-on operation can be seen more clearly in FIG. 3 and the switching-off operation can be seen more clearly in FIG. 4, to which reference is made below.

In order to switch on the field effect transistor M9, firstly a ground potential is applied at the output A1 of the microprocessor MP, whereby the first bipolar transistor Q5 switches on. A switching on of the first bipolar transistor Q5 causes the second bipolar transistor Q7 to switch on, which thereupon generates a collector current that essentially flows as gate current I_{G} into the gate of the field effect transistor M9. The second field effect transistor Q9 is initially turned off owing to the fact that the voltage at the output A1 of the microprocessor MP is at ground potential. As a result of the gate of the field effect transistor M9 being flooded with charge carriers, the field effect transistor is switched on within 200 ns, see the rise in the gate voltage U_{G} of the field effect transistor M9 from 0 V to approximately 12 V in FIG. 3.

In order to switch off the field effect transistor M9, a 5 V signal is provided at the output A1 of the microprocessor MP, whereby the bipolar transistor Q5 is turned off and the field effect transistor Q9 is turned on. As a result, the gate terminal of the field effect transistor M9 is connected to the ground potential and charge carriers are enabled to flow away from the gate of M9, which results in a gate current I_{G} having a negative amplitude. The overshoot results from an oscillation on account of the Miller capacitance of the field effect transistor M9 and the inductive load L9. After the discharge of the gate, the gate current I_{G} returns to 0 A again. The gate current I_{G} having a negative amplitude leads to a switching off of the field effect transistor M9 within 20 ns, see the profile of the gate voltage U_{G} in FIG. 4.

If the two bipolar transistors of the driver stage were operated as an emitter follower, i.e. in common-collector connection, such short switching times, as illustrated in FIGS. 3 and 4, could not be obtained. In the switched-off state, i.e. the bipolar transistor Q5 is turned off, as a result the bipolar transistor Q7 is turned off, the field effect transistor Q9 is turned on, the field effect transistor M9 is switched off, the quiescent current consumption is 0. An improvement of the circuit arrangement illustrated in FIG. 1 can be achieved if, at the output of the field effect transistor Q9, a pull-down resistor R1 is arranged which, in the start-up phase of the overall circuit, ensures that the MOSFET M9 is reliably turned off.

The circuit arrangement illustrated in FIG. 1 furthermore operates without problems that might be caused by inverse operation of the transistor Q5 operated in common-emitter connection at a supply voltage V1<V7. Under certain circumstances, the output of the microprocessor MP would thereby be clamped externally to an excessively low voltage that might adversely influence the function of the microprocessor MP. Moreover, this might lead to destruction of the microprocessor MP as a result of the overloading of its output. In the solution according to the invention, this problem is avoided by the use of the antisaturation diodes D86 and D87, which simultaneously serve as inverse protection diodes for the transistor Q5. If said diodes are not used, said problem can be solved if the microprocessor MP is switched to logic high or tristate with high impedance.

In the temporal profiles of FIG. 2 to FIG. 4, in the exemplary embodiment taken as a basis, the electronic semiconductor components of the circuit arrangement from FIG. 1 were realized by the following components: Q5 by a BC846A, Q7 by a BC807-40, D86 and D87 by respectively a D1N4148, Q9 by a BSS87/SIE, M9 by an IRF830,D72 by a D1N4937, D78 by a D1N5254. Inexpensive alternatives for Q9 would be for example a BSS98, a BSS123 and a 2N7002.

1. A circuit arrangement for driving an electronic component with the output signal (V6) from a microprocessor (MP), comprising:
the electronic component with a control input;
a microprocessor (MP), which provides an output signal (V6) at an output (A1);
characterized
in that it furthermore comprises:
a first bipolar transistor (Q5) in common-base connection, the emitter of which is coupled to the output (A1) of the microprocessor (MP);
a second bipolar transistor (Q7) in common-emitter connection, the base of which is coupled to the collector of the first bipolar transistor (Q5), the collector of the second bipolar transistor (Q7) being coupled to the control input of the electronic component.

2. The circuit arrangement as claimed in claim 1,
characterized
in that the microprocessor (MP) has an input via which it is coupled to a first reference potential (V7), the base of the first bipolar transistor (Q5) being coupled to the reference potential (V7) of the microprocessor (MP).

3. The circuit arrangement as claimed in claim 1,
characterized
in that a first antisaturation diode (D86) is coupled between the collector of the first bipolar transistor (Q5) and the base of the second bipolar transistor (Q7) and a second antisaturation diode (D87) is coupled between the collector of the first bipolar transistor (Q5) and the collector of the second bipolar transistor (Q7).

4. The circuit arrangement as claimed in claim 1,
characterized
in that it comprises a further transistor (M9), preferably a MOSFET, in particular an n-channel MOSFET, the control electrode of which is coupled to the output (A1) of the microprocessor (MP), the reference electrode of which is coupled to a second reference potential, in particular to ground, and the working electrode of which is coupled to the control input of the electronic component.

5. The circuit arrangement as claimed in claim 4,
characterized
in that the control input of the electronic component is coupled to the second reference potential via a pull-down resistor (R1).

6. The circuit arrangement as claimed in claim 1,
characterized
in that the voltage swing of the output signal (V6) at the output (A1) of the microprocessor (MP) is at most 6 V.

7. The circuit arrangement as claimed in claim 1,
characterized
in that the first bipolar transistor (Q5) is of the npn type.

8. The circuit arrangement as claimed in claim 1,
characterized
in that the second bipolar transistor (Q7) is of the pnp type.

9. The circuit arrangement as claimed in claim 1,
characterized
in that the electronic component is an essentially voltage-controlled electronic component.

10. The circuit arrangement as claimed in claim 1,
characterized
in that the electronic component is a MOSFET, an IGBT or an ESBT.

11. A method for driving an electronic component with the output signal (V6) from a microprocessor (MP), characterized by the following steps:
a) the output signal (V6) of the microprocessor (MP) is coupled to the emitter of a first bipolar transistor (Q5) in common-base connection;
b) the collector of the first bipolar transistor (Q5) is coupled to the base of a second bipolar transistor (Q7) in common-emitter connection, the collector of the second bipolar transistor (Q7) being coupled to the control input of the electronic component.

12. The circuit arrangement as claimed in claim 2,
characterized
in that a first antisaturation diode (D86) is coupled between the collector of the first bipolar transistor (Q5) and the base of the second bipolar transistor (Q7) and a second antisaturation diode (D87) is coupled between the collector of the first bipolar transistor (Q5) and the collector of the second bipolar transistor (Q7).

13. The circuit arrangement as claimed in claim 2,
characterized
in that it comprises a further transistor (M9), preferably a MOSFET, in particular an n-channel MOSFET, the control electrode of which is coupled to the output (A1) of the microprocessor (MP), the reference electrode of which is coupled to a second reference potential, in particular to ground, and the working electrode of which is coupled to the control input of the electronic component.

14. The circuit arrangement as claimed in claim 2,
characterized
in that the voltage swing of the output signal (V6) at the output (A1) of the microprocessor (MP) is at most 6 V.

15. The circuit arrangement as claimed in claim 2,
characterized
in that the first bipolar transistor (Q5) is of the npn type.

16. The circuit arrangement as claimed in claim 2,
characterized
in that the second bipolar transistor (Q7) is of the pnp type.

17. The circuit arrangement as claimed in claim 2,
characterized
in that the electronic component is an essentially voltage-controlled electronic component.

18. The circuit arrangement as claimed in claim 2,
characterized
in that the electronic component is a MOSFET, an IGBT or an ESBT.
